(19) United States
(12) Patent Application Publication
(10) Pub. No.: US 2026/0103094 A1
(43) Pub. Date: Apr. 16, 2026

(54) METHOD AND APPARATUS FOR DIAGNOSING DOUBLE FUSION IN VEHICLE BATTERY CHARGING SYSTEM

(71) Applicants: Hyundai Motor Company, Seoul (KR); Kia Corporation, Seoul (KR)

(72) Inventors: Jin Su Hong, Hwaseong-si (KR); Ho Joon Shin, Hwaseong-si (KR); Seong Won Choi, Hwaseong-si (KR); Eun Cheon Bae, Hwaseong-si (KR); Dong Jun Lee, Hwaseong-si (KR); Yong Jae Lee, Hwaseong-si (KR)

(21) Appl. No.: 19/048,005

(22) Filed: Feb. 7, 2025

(30) Foreign Application Priority Data
Oct. 11, 2024 (KR) 10-2024-0138833

(51) Int. Cl. B60L 53/10; B60L 53/62; G01R 31/327; H02J 7/00

(52) U.S. Cl. CPC B60L 53/10; B60L 53/62; G01R 31/3278; H02J 7/865

(57) ABSTRACT

An apparatus for diagnosing dual fusion can include an inlet sharing a DC charging port and an AC charging port, a DC charging system electrically connected to a first current carrying path, a first relay group disposed on the first current carrying path, an AC charging system electrically connected to a second current carrying path branched from the inlet, a second relay group disposed on the second current carrying path and selectively connecting the inlet and the AC charging system, and a controller configured to, in order to diagnose dual fusion of one of the first relay group and the second relay group, close the other one, generate a constant voltage in a charging system connected to the one relay group between the DC charging system and the AC charging system, and measure a voltage detected at an input terminal of a charging system connected to the other relay group.

### CROSS-REFERENCE TO RELATED APPLICATIONS

This application claims priority from Korean Patent Application No. 10-2024-0138833, filed on Oct. 11, 2024 in the Korean Intellectual Property Office, the disclosure of which is incorporated herein by reference in its entirety.

### TECHNICAL FIELD

The present disclosure relates to a method and apparatus for diagnosing double relay fusion in a vehicle battery charging system.

### BACKGROUND

In general, electric vehicles or hybrid vehicles include an energy storage device (e.g., a battery) that receives and stores AC grid power using a charging facility. To charge the energy storage device, vehicles include a charging device that converts AC grid power provided from an external charging facility into DC power of a desired level.

Among technologies used in a charging system mounted in vehicles, North American Charging Standard (NACS) is an electric vehicle charging standard widely used in North America. The NACS standard was developed by Tesla for its electric vehicle charger, “Supercharger”, and supports both AC and DC power.

The NACS is widely used in North America because it has a high charging speed and high compatibility with various electric vehicle models, and many electric vehicle manufacturers have recently adopted NACS.

In a typical NACS charging system that supports slow charging and rapid charging, as shown in FIG. 1, one NACS inlet 130 can be used for both slow charging using a slow charger 110 and rapid charging using a rapid charger 120. When a low voltage for slow charging of a vehicle is input from the outside, power is supplied to a slow charging circuit 150 through a slow charging relay 140, and when a high voltage for rapid charging of a vehicle is input, power is supplied to a rapid charging circuit 170 through a rapid charging relay 160.

However, when double fusion has occurred in the rapid charging relay 160 in NACS, an inrush current may occur in an inverter or a charger, which may damage the inverter or the charger, and when double fusion has occurred in the slow charging relay 140, an excess voltage may be input to an integrated charging control unit (ICCU), which may damage the ICCU.

Accordingly, there is a demand in this technical field for a technology capable of diagnosing double fusion of a relay in a vehicle battery charging system supporting NACS.

### SUMMARY

The present disclosure relates to eco-friendly vehicle charging technology, and more specifically, to a method and apparatus for diagnosing double relay fusion in a vehicle battery charging system.

Therefore, the present disclosure has been made in view of the above problems, and an embodiment of the present disclosure can diagnose double fusion of a relay in a vehicle battery charging system supporting NACS.

An embodiment of the present disclosure can diagnose double fusion of a relay by utilizing an inverter and an on-board charger (OBC) without a separate diagnostic control circuit for double fusion diagnosis.

The technical advantages to be achieved by embodiments of the present disclosure are not necessarily limited to the technical advantages mentioned above, and other technical advantages not mentioned can be understood by a person having ordinary knowledge in the technical field to which the present disclosure belongs from the description below.

In accordance with an embodiment of the present disclosure, an apparatus for diagnosing dual fusion can include an inlet sharing a DC charging port and an AC charging port, a DC charging system electrically connected to a first current carrying path branched from the inlet and including a motor and an inverter, a first relay group disposed on the first current carrying path and selectively connecting the inlet and the DC charging system, an AC charging system electrically connected to a second current carrying path branched from the inlet, a second relay group disposed on the second current carrying path and selectively connecting the inlet and the AC charging system, and a controller configured to, in order to diagnose dual fusion of one of the first relay group and the second relay group, close the other one, generate a constant voltage in a charging system connected to the one relay group between the DC charging system and the AC charging system, and measure a voltage detected at an input terminal of a charging system connected to the other relay group.

The first current carrying path may include a DC positive (+) line and a DC negative (−) line, and the first relay group may include a first relay on the DC positive (+) line and a second relay on the DC negative (−) line.

The second current carrying path may include an AC1 line and an AC2 line, and the second relay group may include a third relay on the AC1 line and a fourth relay on the AC2 line.

The controller may control the constant voltage to be generated at a neutral point of the motor during diagnosis of double fusion of the first relay group.

The controller may control the constant voltage to be generated in the DC charging system during diagnosis of double fusion of the second relay group.

The controller may determine whether double fusion has occurred in the first relay group based on a voltage measured at an input terminal of the AC charging system during diagnosis of double fusion of the first relay group.

The controller may determine that double fusion has occurred in the first relay group when the voltage measured at the input terminal of the AC charging system is higher than a threshold voltage.

The controller may determine whether double fusion has occurred in the second relay group based on a voltage measured at an input terminal of the DC charging system during diagnosis of double fusion of the second relay group.

The controller may determine that double fusion has occurred in the second relay group when the voltage measured at the input terminal of the DC charging system is higher than a threshold voltage.

In accordance with an embodiment of the present disclosure, a method of diagnosing double fusion can include, in order to diagnose double fusion of one of a first relay group and a second relay group, closing the other one, the first relay group being disposed on a first current carrying path branched from an inlet sharing a DC charging port and an AC charging port and selectively connecting the inlet and a DC charging system, the second relay group being disposed on a second current carrying path branched from the inlet and selectively connecting the inlet and an AC charging system, generating a constant voltage in a charging system connected to the one relay group between the DC charging system and the AC charging system, and measuring a voltage detected at an input terminal of a charging system connected to the other relay group.

The method may further include determining whether double fusion has occurred in the one relay group based on the voltage detected at the input terminal of the charging system connected to the other relay group.

The determining whether double fusion has occurred may include determining whether double fusion has occurred in the first relay group based on a voltage measured at an input terminal of the AC charging system during diagnosis of double fusion of the first relay group.

The determining whether double fusion has occurred may include determining that double fusion has occurred in the first relay group when the voltage measured at the input terminal of the AC charging system is higher than a threshold voltage.

The determining whether double fusion has occurred may include determining whether double fusion has occurred in the second relay group based on a voltage measured at an input terminal of the DC charging system during diagnosis of double fusion of the second relay group.

The determining whether double fusion has occurred may include determining that double fusion has occurred in the second relay group when the voltage measured at the input terminal of the DC charging system is higher than a threshold voltage.

### BRIEF DESCRIPTION OF THE DRAWINGS

The above and other features and other advantages of example embodiments of the present disclosure can be more clearly understood from the following detailed description taken in conjunction with the accompanying drawings, in which:

FIG. 1 shows an example of a general NACS charging system that supports slow charging and rapid charging to which an embodiment of the present disclosure can be applicable;

FIG. 2 shows an example of a double fusion diagnostic apparatus according to an embodiment of the present disclosure;

FIG. 3 shows an example of diagnosing double fusion of a first relay group according to an on/off state of each relay and a voltage measured by a voltage sensor in the double fusion diagnostic apparatus of the embodiment illustrated in FIG. 2;

FIG. 4 shows an example of diagnosing double fusion of a second relay group according to an on/off state of each relay and a voltage measured by a voltage sensor in the double fusion diagnostic apparatus of the embodiment illustrated in FIG. 2;

FIG. 5 is a block diagram schematically showing an example of a double fusion diagnostic apparatus according to an embodiment of the present disclosure;

FIG. 6 is a flowchart showing a double fusion diagnosis method of a vehicle battery charging apparatus according to an embodiment of the present disclosure; and

FIG. 7 is a flowchart showing a double fusion diagnosis method of a vehicle battery charging device according to an embodiment of the present disclosure.

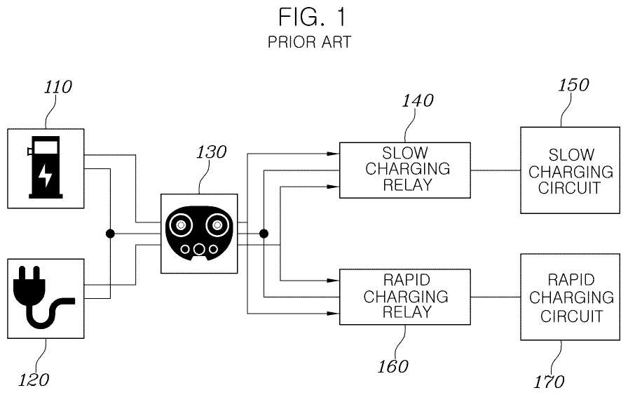

### DETAILED DESCRIPTION OF ILLUSTRATIVE EMBODIMENTS

Hereinafter, example embodiments disclosed in this specification will be described in detail with reference to the attached drawings. Regardless of symbols, identical or similar components can be given same reference numerals and redundant descriptions thereof can be omitted. The suffixes “module” and “unit” of elements used in the following description can be used for convenience of description and thus can be used interchangeably. When describing example embodiments disclosed in this specification, if it is determined that a specific description of a related known technology may obscure the gist of the example embodiments disclosed in this specification, the detailed description thereof can be omitted. The attached drawings are intended to facilitate easy understanding of the example embodiments disclosed in this specification, and technical ideas disclosed in this specification are not necessarily limited by the attached drawings and can be understood to include all modifications, equivalents, and substitutes included in the spirit and technical scopes of the present disclosure.

Terms including ordinal numbers such as “first” and “second” may be used to describe various components, but the components are not necessarily limited by such terms. Such terms can be used merely for the purpose of distinguishing one component from another.

When a component is referred to as being “coupled” or “connected” to another component, it can be understood that the component may be directly coupled or connected to the other component, but there may be other components therebetween. On the other hand, when a component is referred to as being “directly coupled” or “directly connected” to another component, it can be understood that there are no other components therebetween.

A singular expression can include a plural expression thereof unless the context clearly indicates otherwise.

In this specification, the term “comprise” or “have” is intended to specify the presence of a feature, number, step, operation, component, part, or combination thereof described in the specification, but should be understood not to preclude the presence or addition of one or more other features, numbers, steps, operations, components, parts, or combinations thereof.

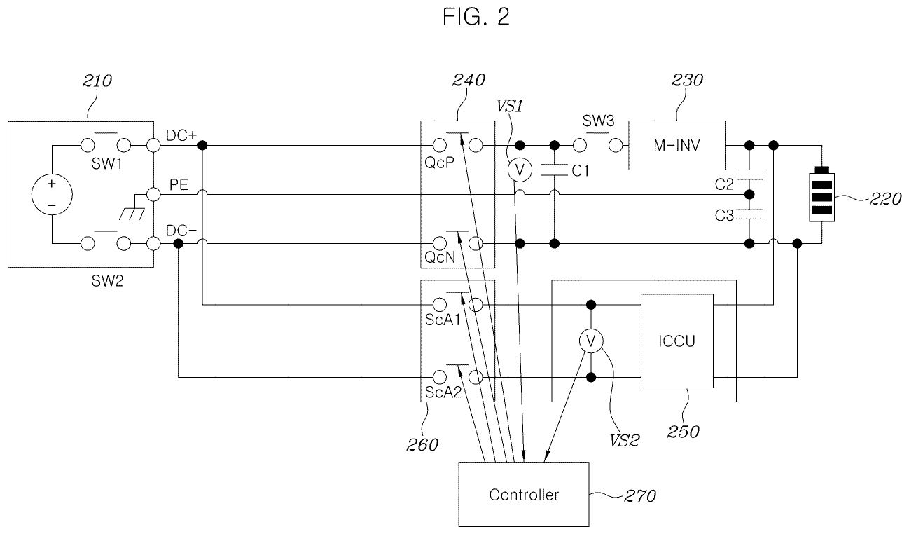

FIG. 2 shows an example of a dual fusion diagnostic apparatus according to an embodiment of the present disclosure.

Referring to FIG. 2, the dual fusion diagnostic apparatus according to an embodiment of the present embodiment can include an inlet 210 connected to an external power supply to receive power, first and second switches SW1 and SW2 for controlling power supply within the inlet 210, a battery 220 charged with power through the external power supply connected to the inlet 210 and supplies power using the charged energy when a vehicle is driven, a direct current (DC) charging system 230 electrically connected to a first current carrying path branched from the inlet 210, a first relay group 240 arranged on the first current carrying path, an alternating current (AC) charging system 250 electrically connected to a second current carrying path branched from the inlet 210, a second relay group 260 arranged on the second current carrying path, a first voltage sensor VS1 for measuring a voltage at an input terminal of the DC charging system 230, a second voltage sensor VS2 for measuring a voltage at an input terminal of the AC charging system 250, and a controller 270 that diagnoses double fusion of one of the first relay group and the second relay group by controlling the first and second relay groups 240 and 260 and the first and second voltage sensors VS1 and VS2.

Although FIG. 2 illustrates that the inlet 210 receives power from a DC power supply, the inlet 210 may receive power from a DC power supply that supports rapid charging or from an AC power supply that supports slow charging by sharing a DC charging port and an AC charging port.

The current carrying path connected from the inlet 210 to the battery 220 can be divided into a first current carrying path and a second current carrying path.

The first current carrying path can include a DC positive (+) line and a DC negative (−) line, and the first relay group can include a first relay QcP on the DC positive (+) line and a second relay QcN on the DC negative (−) line.

The second current carrying path can include an AC1 line and an AC2 line, and the second relay group can include a third relay ScA1 on the AC1 line and a fourth relay ScA2 on the AC2 line.

The DC charging system 230 may include a motor and an inverter.

The DC charging system 230 may directly transfer DC charging power to the battery 220 without boosting when the voltage of the DC charging power supplied from the outside is suitable for charging the battery 220, for example when the charging voltage is higher than the voltage of the battery 220, and when the charging voltage is lower than the voltage of the battery 220, may charge the battery 220 by boosting the voltage of charging power input through a motor neutral point through a boost converter topology configured using motor winding and a switch of an inverter.

The AC charging system 250 may be an on-board charger (OBC) of the vehicle or a component corresponding thereto. For example, the AC charging system 250 may be implemented as an OBC or an integrated charging control unit (ICCU) in which an OBC and a DC-DC converter are integrated.

The first and second relays QcP and QcN can be disposed on the first current carrying path branched from the inlet 210 such that the inlet 210 and the DC charging system 230 can be selectively connected.

The third and fourth relays ScA1 and ScA2 can be disposed on the second current carrying path branched from the inlet 210 such that the inlet 210 and the AC charging system 250 can be selectively connected.

The controller 270 can control the first to fourth relays QcP, QcN, ScA1, and ScA2, and diagnose double fusion of the first and second relays QcP and QcN or the third and fourth relays ScA1 and ScA2 according to voltage measurement values of the first and second voltage sensors VS1 and VS2.

The controller 270 may determine whether double fusion has occurred in the first and second relays QcP and QcN by short-circuiting the third and fourth relays ScA1 and ScA2 before receiving power from the external power supply connected to the inlet 210, i.e., while power supply from the external power supply is cut off.

Double fusion can refer to two switches that are closed at the same time when they should be open. If double fusion has occurred in the first and second relays QcP and QcN, the voltage generated by the DC charging system 230 can be applied to the AC charging system 250 when the third and fourth relays ScA1 and ScA2 are short-circuited, and if the first and second relays QcP and QcN operate normally, no voltage should be applied to the AC charging system 250 even after the third and fourth relays ScA1 and ScA2 are short-circuited.

On the other hand, in an embodiment, it is possible to determine whether double fusion has occurred in the third and fourth relays ScA1 and ScA2 by short-circuiting the first and second relays QcP and QcN while power supply from the external power supply connected to the inlet 210 is cut off.

When double fusion has occurred in the third and fourth relays ScA1 and ScA2, the voltage generated by the AC charging system 250 can be applied to the DC charging system 230 when the first and second relays QcP and QcN are short-circuited, and if the third and fourth relays ScA1 and ScA2 operate normally, no voltage should be applied to the DC charging system 230 even after the first and second relays QcP and QcN are short-circuited.

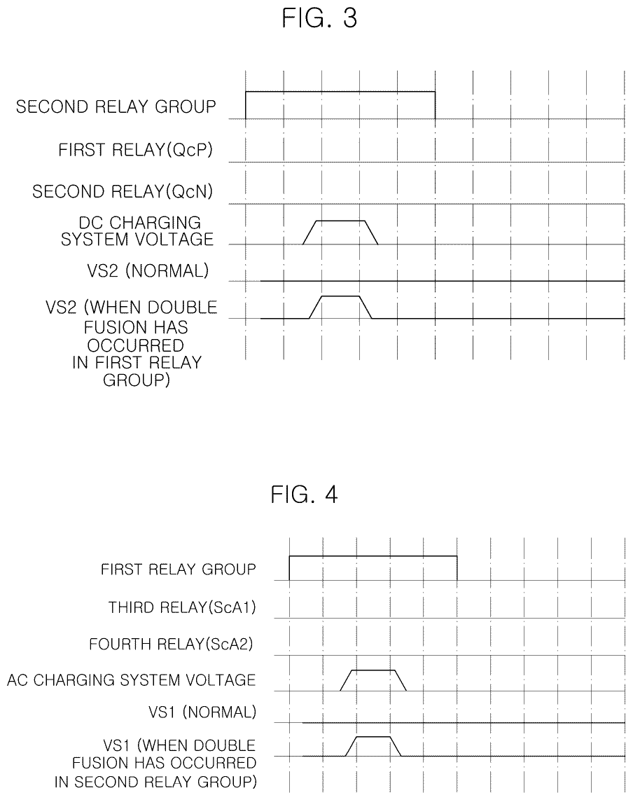

FIG. 3 shows an example of diagnosing double fusion of the first relay group according to an on/off state of each relay and a voltage measured by a voltage sensor in the double fusion diagnostic apparatus of the embodiment of FIG. 2.

Referring to FIG. 2 and FIG. 3, when a voltage is generated at the neutral point of a motor (not shown) constituting the DC charging system 230 in a state in which power supply from the inlet 210 is cut off and the third and fourth relays ScA1 and ScA2, i.e., the second relay group 260, are short-circuited, the voltage of the second voltage sensor VS2 can be measured as zero in a normal situation, but when double fusion has occurred in the first and second relays QcP and QcN, i.e., the first relay group 240, a constant voltage can be measured by the second voltage sensor VS2.

The same voltage as the voltage generated at the neutral point of the motor can be measured by the second voltage sensor VS2.

For example, if the voltage generated at the neutral point of the motor is 60 V, a voltage of 60 V can also be measured by the second voltage sensor VS2.

Therefore, when the voltage is generated at the neutral point of the motor (not shown) constituting the DC charging system 230 while the second relay group is short-circuited, using an embodiment, it can be possible to determine whether double fusion has occurred in the first relay group 240 based on a voltage value measured by the second sensor VS2.

FIG. 4 shows an example of diagnosing double fusion of the second relay group according to an on/off state of each relay and a voltage measured by a voltage sensor in the double fusion diagnostic apparatus of the embodiment of FIG. 2.

Referring to FIG. 2 and FIG. 4, when a voltage is generated in the AC charging system 250 in a state in which power supply from the inlet 210 is cut off and the first and second relays QcP and QcN, i.e., the first relay group 240, are short-circuited, the voltage of the first voltage sensor VS1 can be measured as zero in a normal situation, but when double fusion has occurred in the third and fourth relays ScA1 and ScA2, i.e., the second relay group 260, a constant voltage can be measured by the first voltage sensor VS1.

The same voltage as the voltage generated in the AC charging system 250 can be measured by the first voltage sensor VS1.

For example, when the voltage generated in the AC charging system 250 is 60 V, a voltage of 60 V can also be measured by the first voltage sensor VS1.

Accordingly, using an embodiment, when a voltage is generated in the AC charging system 250 while the first relay group 240 is short-circuited, it can be possible to determine whether double fusion has occurred in the second relay group 260 based on a voltage value measured by the first sensor VS1.

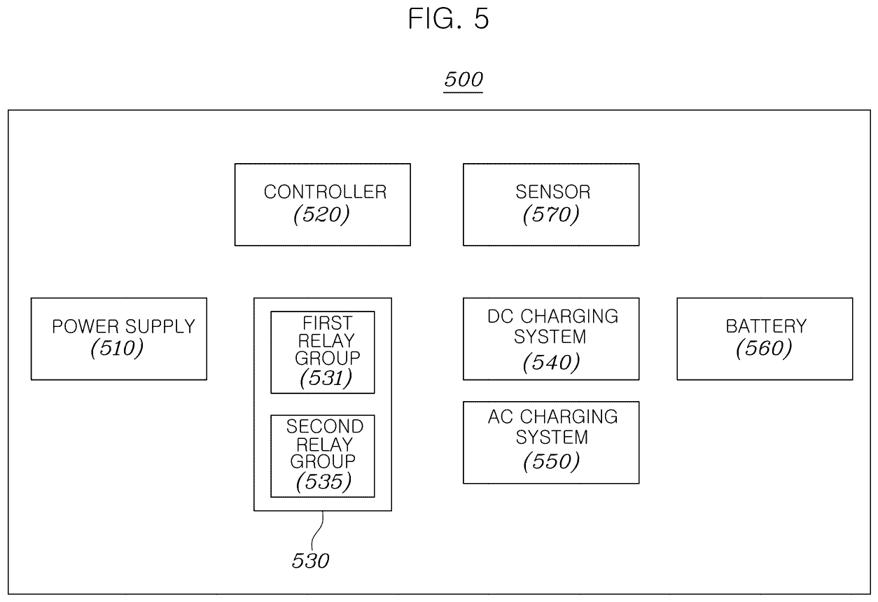

FIG. 5 is a block diagram schematically illustrating an example of a dual fusion diagnostic apparatus according to an embodiment of the present disclosure.

Referring to FIG. 5, a dual fusion diagnostic apparatus 500 according to an embodiment of the present disclosure can include a power supply 510, a controller 520, a relay 530, a DC charging system 540, an AC charging system 550, a battery 560, and a sensor 570, any of, any combination of, or all of which may be in plural or may include plural components thereof.

The power supply 510 can supply power for charging a battery 560.

The power supply 510 may include a NACS inlet.

The inlet can share a DC charging port and an AC charging port, and may receive a DC voltage or an AC voltage.

The controller 520 can close the first relay group 531 to charge the battery 560 through the DC charging system 540 when a DC voltage is input to the power supply 510 from the outside, and close the second relay group 535 to charge the battery 560 through the AC charging system 550 when an AC voltage is input.

In an embodiment, the controller 520 may operate in a dual fusion diagnosis mode for diagnosing dual fusion of the first relay group 531 or the second relay group 535.

In an embodiment, the controller 520 may operate in a mode for diagnosing dual fusion of the first relay group 531 when an AC voltage is input to the power supply 510 from the outside.

In the double fusion diagnosis mode for the first relay group 531, the controller 520 can short-circuit the second relay group 535, generate a constant voltage in the DC charging system 230, and measure the voltage of the input terminal of the AC charging system 550.

The controller 520 may generate a constant voltage at the neutral point of the motor included in the DC charging system 230.

If the voltage is not measured at the input terminal of the AC charging system 550, the controller 520 can determine that double fusion has not occurred in the first relay group 531.

If a voltage higher than a threshold voltage is measured at the input terminal of the AC charging system 550, the controller 520 can determine that double fusion has occurred in the first relay group 531.

The threshold voltage may be any voltage selected by a user to determine double fusion of the first relay group 531.

In an embodiment, if a DC voltage is input to the power supply 510 from the outside, the controller 520 may operate in a mode for diagnosing double fusion of the second relay group 535.

In the double fusion diagnosis mode for the second relay group 535, the controller 520 can short-circuit the first relay group 531, generate a constant voltage in the AC charging system 250, and measure the voltage of the input terminal of the DC charging system 540.

If no voltage is measured at the input terminal of the DC charging system 540, the controller 520 can determine that double fusion has not occurred in the second relay group 535.

On the other hand, if a voltage higher than a threshold voltage is measured at the input terminal of the DC charging system 540, the controller 520 can determine that double fusion has occurred in the second relay group 535.

The threshold voltage may be any voltage selected by the user to determine double fusion of the first relay group 531.

The relay 530 can be selectively short-circuited or opened under the control of the controller 520 and can include the first relay group 531 and the second relay group 535.

The DC charging system 540 can convert DC high-voltage power input to the power supply 510 to charge the battery 560 under the control of the controller 520 when the DC voltage power is input to the power supply 510.

The AC charging system 550 can convert AC low-voltage power input to the power supply 510 to charge the battery 560 under the control of the controller 520 when the AC voltage power is input to the power supply 510.

The battery 560 can charge power using the power supplied from the power supply 510, and supply power using the charged energy when the vehicle operates.

The sensor 570 can measure the voltage of the DC charging system 540 or the AC charging system 550 to diagnose double fusion of the first relay group 531 or the second relay group 535.

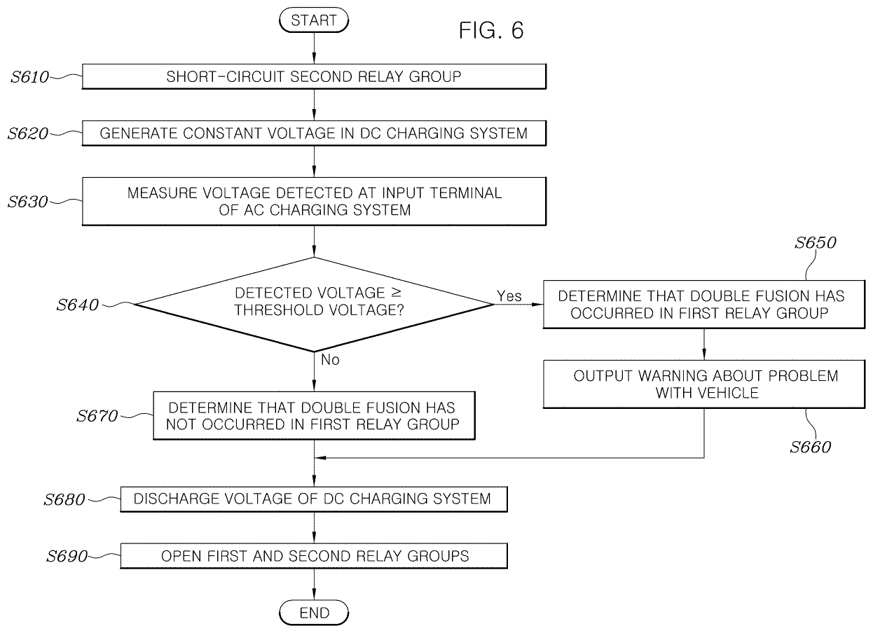

FIG. 6 is a flowchart showing a double fusion diagnosis method of a vehicle battery charging system according to an embodiment of the present disclosure.

The double fusion diagnosis method according to an embodiment of the present embodiment may be performed by the controller 270 of the embodiment illustrated in FIG. 2.

Referring to FIG. 6, the controller 270 can short-circuit the second relay group 260 (S610), generate a constant voltage in the DC charging system 230 (operation S620), and measure the voltage detected at the input terminal of the AC charging system 250 (operation S630).

In operation S620, the controller 270 may control the DC charging system 230 such that a constant voltage can be generated at the neutral point of the motor included in the DC charging system 230.

The controller 270 can determine whether the voltage detected at the input terminal of the AC charging system 250 is higher than a threshold voltage (operation S640), and if the detected voltage is higher than the threshold voltage, determine that double fusion has occurred in the first relay group 240 (operation S650), output a warning that there is a problem with the vehicle (operation S660), and discharge the neutral point voltage of the motor (operation S680).

The warning that there is a problem with the vehicle may be performed by displaying a warning message on a display screen inside the vehicle and/or by outputting a warning sound through a speaker provided in the vehicle.

If the detected voltage is lower than the threshold voltage as a result of determination in operation S640, the controller 270 can determine that double fusion has not occurred in the first relay group 240 (operation S670) and discharge the voltage of the DC charging system 230 (operation S680). The controller 270 can open the first and second relay groups 240 and 260 (operation S690), and end the procedure.

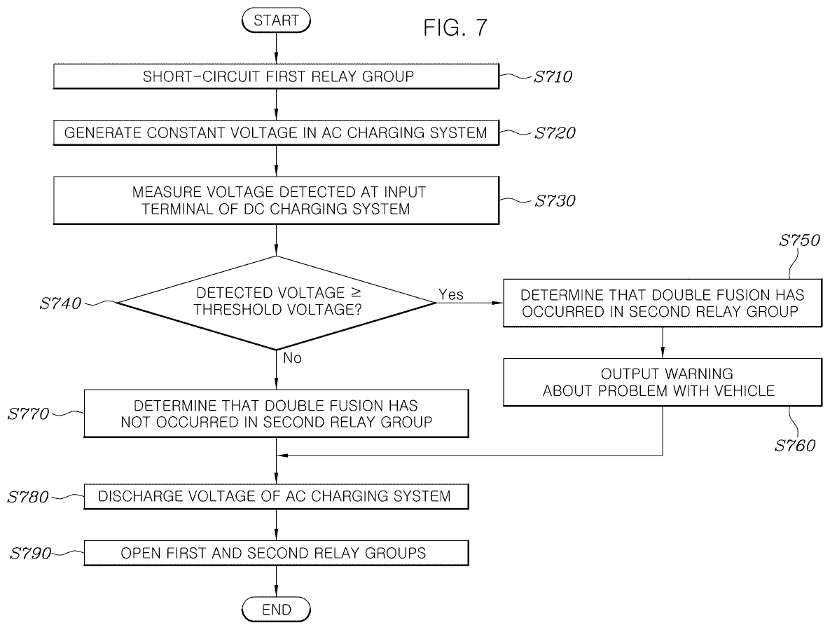

FIG. 7 is a flowchart showing a double fusion diagnosis method of a vehicle battery charging system according to an embodiment of the present disclosure.

The double fusion diagnosis method according to an embodiment of the present embodiment may be performed by the controller 270 of the embodiment illustrated in FIG. 2.

Referring to FIG. 7, the controller 270 can short-circuit the first relay group 240 (operation S710), generate a constant voltage in the AC charging system 250 (operation S720), and measure the voltage detected at the input terminal of the DC charging system 230 (operation S730).

The controller 270 can determine whether the voltage detected at the input terminal of the DC charging system 230 is higher than a threshold voltage (operation S740), and if the detected voltage is higher than the threshold voltage, determine that double fusion has occurred in the second relay group 260 (operation S750), output a warning about a problem with the vehicle (operation S760), and discharge the voltage of the AC charging system (operation S780).

The warning about a problem with the vehicle may be performed by displaying a warning message on a display screen inside the vehicle and/or by outputting a warning sound through a speaker provided in the vehicle.

If the detected voltage is lower than the threshold voltage as a result of determination in operation S740, the controller 270 can determine that double fusion has not occurred in the second relay group 260 (operation S770) and discharge the voltage of the AC charging system 250 (operation S780). The controller 270 can open the first and second relay groups 240 and 260 (operation S790), and end the procedure.

According to the example embodiments of the present disclosure described above, double fusion of a relay can be diagnosed in an eco-friendly vehicle charging system in which a slow charging relay and a rapid charging relay are present.

According to an embodiment of the present disclosure, double fusion of a relay can be diagnosed by utilizing an inverter and an OBC without a separate diagnostic control circuit for double fusion diagnosis.

The above-described example embodiments of the present disclosure can be implemented as computer-readable code on a medium in which a program is recorded. Computer-readable media can include all kinds of recording devices in which data that can be read by a computer system is stored. Examples of computer-readable media can include a hard disk drive (HDD), a solid state drive (SSD), a silicon disk drive (SDD), a ROM, a RAM, a CD-ROM, a magnetic tape, a floppy disk, an optical data storage device, etc. Therefore, the above detailed description should not be construed as necessarily limiting and can be considered as illustrative using example embodiments. The scopes of the present disclosure can be determined by a reasonable interpretation of the appended claims, and changes within equivalent scopes of the present disclosure can be included in the scopes of the present disclosure.

According to various embodiments of the present disclosure as described above, it can be possible to diagnose double fusion of a relay in a vehicle battery charging system supporting NACS.

According to various embodiments of the present disclosure as described above, it can be possible to diagnose double fusion of a relay by utilizing an inverter and an OBC without a separate diagnostic control circuit for double fusion diagnosis.

Although the example embodiments of the present disclosure have been disclosed for illustrative purposes, those skilled in the art can appreciate that various modifications, additions, and substitutions can be possible, without departing from the scopes and spirit of the present disclosure as disclosed in the accompanying claims.

What is claimed is:

1. An apparatus for diagnosing dual relay fusion, comprising:
an inlet configured to share a DC charging port and an AC charging port;
a DC charging system electrically connected to a first current carrying path branched from the inlet and including a motor and an inverter;
a first relay group disposed on the first current carrying path and configured to selectively connect the inlet and the DC charging system;
an AC charging system electrically connected to a second current carrying path branched from the inlet;
a second relay group disposed on the second current carrying path and configured to selectively connect the inlet and the AC charging system; and
a controller configured to diagnose dual fusion of one target group selected from the first relay group and the second relay group, by being configured to:
close an oppositely corresponding non-selected group of the first relay group and the second relay group,
generate a constant voltage in a corresponding first charging system connected to the selected one target group among the DC charging system and the AC charging system, and
measure a detected voltage detected at an input terminal of a corresponding second charging system connected to the oppositely corresponding non-selected group.

2. The apparatus of claim 1, wherein the first current carrying path comprises a DC positive (+) line and a DC negative (−) line, and wherein the first relay group comprises a first relay on the DC positive (+) line and a second relay on the DC negative (−) line.

3. The apparatus of claim 1, wherein the second current carrying path comprises an AC1 line and an AC2 line, and wherein the second relay group comprises a third relay on the AC1 line and a fourth relay on the AC2 line.

4. The apparatus of claim 1, wherein the controller is further configured to control the constant voltage to be generated at a neutral point of the motor during diagnosis of double fusion of the first relay group.

5. The apparatus of claim 1, wherein the controller is further configured to control the constant voltage to be generated in the DC charging system during diagnosis of double fusion of the second relay group.

6. The apparatus of claim 1, wherein the controller is further configured to determine whether double fusion has occurred in the first relay group based on the detected voltage measured at the input terminal of the AC charging system during diagnosis of double fusion of the first relay group.

7. The apparatus of claim 6, wherein the controller is further configured to determine that double fusion has occurred in the first relay group in response to the detected voltage measured at the input terminal of the AC charging system being higher than a threshold voltage.

8. The apparatus of claim 1, wherein the controller is further configured to determine whether double fusion has occurred in the second relay group based on the detected voltage measured at the input terminal of the DC charging system during diagnosis of double fusion of the second relay group.

9. The apparatus of claim 8, wherein the controller is further configured to determine that double fusion has occurred in the second relay group in response to the detected voltage measured at the input terminal of the DC charging system being higher than a threshold voltage.

10. A method of diagnosing double relay fusion, comprising diagnosing double fusion of one target group selected from a first relay group and a second relay group, wherein the first relay group is disposed on a first current carrying path branched from an inlet configured to share a DC charging port and an AC charging port, wherein the first relay group is configured to selectively connect the inlet and a DC charging system, wherein the second relay group is disposed on a second current carrying path branched from the inlet, wherein the second relay group is configured to selectively connect the inlet and an AC charging system, and wherein the diagnosing comprises:
closing an oppositely corresponding non-selected group of the first relay group and the second relay group;
generating a constant voltage in a corresponding first charging system connected to the selected one target group among the DC charging system and the AC charging system; and
measuring a detected voltage detected at an input terminal of a corresponding second charging system connected to the oppositely corresponding non-selected group.

11. The method of claim 10, further comprising determining whether double fusion has occurred in the one target group based on the detected voltage detected at the input terminal of the corresponding second charging system connected to the oppositely corresponding non-selected group.

12. The method of claim 11, wherein the determining whether double fusion has occurred comprises determining whether double fusion has occurred in the first relay group based on the detected voltage measured at the input terminal of the AC charging system during diagnosis of double fusion of the first relay group.

13. The method of claim 12, wherein the determining whether double fusion has occurred comprises determining that double fusion has occurred in the first relay group in response to the detected voltage measured at the input terminal of the AC charging system being higher than a threshold voltage.

14. The method of claim 11, wherein the determining whether double fusion has occurred comprises determining whether double fusion has occurred in the second relay group based on the detected voltage measured at the input terminal of the DC charging system during diagnosis of double fusion of the second relay group.

15. The method of claim 14, wherein the determining whether double fusion has occurred comprises determining that double fusion has occurred in the second relay group in response to the detected voltage measured at the input terminal of the DC charging system being higher than a threshold voltage.

16. A method for double relay fusion detection, the method comprising:
sending first control signals for setting a first relay group to open state and setting a second relay group to a closed state, wherein a vehicle battery charging system comprises the first relay group and the second relay group, wherein each of the first relay group and the second relay group comprises two relays, and wherein the vehicle battery charging system further comprises:
an inlet sharing a first charging port and a second charging port, and
a first charging system and a second charging system differing from the first charging system, wherein the first relay group is configured to selectively connect the first charging system to the first charging port, and wherein the second relay group is configured to selectively connect the second charging system to the second charging port,
providing a first voltage in the first charging system while measuring a first detected voltage at a second input terminal of the second charging system; and
determining that the first relay group has a first double relay fusion state in response to the first detected voltage being greater than a first threshold voltage level, or determining that the first relay group does not have the first double relay fusion state in response to the first detected voltage being less than the first threshold voltage level.

17. The method of claim 16, wherein the first charging port is a DC charging port, wherein the first charging system is a DC charging system, wherein the second charging port is an AC charging port, wherein the second charging system is an AC charging system.

18. The method of claim 16, wherein the first charging port is an AC charging port, wherein the first charging system is an AC charging system, wherein the second charging port is a DC charging port, wherein the second charging system is a DC charging system.

19. The method of claim 16, further comprising:
sending second control signals for setting the first relay group to closed state and setting the second relay group to an open state;
providing a second voltage in the second charging system while measuring a second detected voltage at a first input terminal of the first charging system; and
determining that the second relay group has a second double relay fusion state in response to the second detected voltage being greater than a second threshold voltage level, or determining that the second relay group does not have the second double relay fusion state in response to the second detected voltage being less than the second threshold voltage level.

20. The method of claim 19, wherein the first charging port is a DC charging port, wherein the first charging system is a DC charging system, wherein the second charging port is an AC charging port, wherein the second charging system is an AC charging system.
